(19) United States
(12) Patent Application Publication
(10) Pub. No.: US 2026/0022460 A1
(43) Pub. Date: Jan. 22, 2026

(54) FILM FORMATION METHOD AND FILM FORMATION APPARATUS

(71) Applicant: Tokyo Electron Limited, Tokyo (JP)

(72) Inventors: Sakurako NATORI, Nirasaki-shi (JP); Kenichi OYAMA, Tokyo (JP); Tatsuya YAMAGUCHI, Nirasaki-shi (JP); Syuji NOZAWA, Nirasaki-shi (JP)

(21) Appl. No.: 19/339,610

(22) Filed: Sep. 25, 2025

Related U.S. Application Data
(63) Continuation of application No. PCT/JP2024/010526, filed on Mar. 18, 2024.

(30) Foreign Application Priority Data
Mar. 31, 2023 (JP) 2023-057374

(51) Int. Cl. C23C 16/455; C23C 16/44; C23C 16/46; C23C 16/52

(52) U.S. Cl. CPC C23C 16/4554; C23C 16/4408; C23C 16/4412; C23C 16/45544; C23C 16/46; C23C 16/52

(57) ABSTRACT

A film formation method includes: a) loading a substrate including a base film and a resist provided on the base film and having a predetermined pattern formed thereon into a chamber; b) supplying a gas of a first monomer into the chamber; c) supplying a purge gas into the chamber; d) supplying a gas of a second monomer into the chamber to form a polymer film on a surface of the substrate by a polymerization reaction between the first monomer and the second monomer; and e) supplying a purge gas into the chamber, wherein a vapor pressure ratio of the first monomer or the second monomer whichever has a lower saturated vapor pressure is 0.05 or less.

### CROSS-REFERENCE TO RELATED APPLICATION

This application is a Bypass Continuation Application of PCT International Application No. PCT/JP2024/010526, filed on Mar. 18, 2024 and designating the United States, the international application being based upon and claiming the benefit of priority from Japanese Patent Application No. 2023-057374, filed on Mar. 31, 2023, the entire content of which is incorporated herein by reference.

### TECHNICAL FIELD

Various aspects and embodiments of the present disclosure relate to a film formation method and a film formation apparatus.

### BACKGROUND

In Patent Document 1 described below, there is known a semiconductor device manufacturing method that includes: a film formation step of forming a film, which is elastic and immiscible with a resist patterned on a workpiece, so as to cover a surface of the resist by altering a surface layer of the resist; and a heating step of heating the workpiece on which the film is formed.

### PRIOR ART DOCUMENT

### Patent Document

Patent Document 1: Japanese Patent Laid-open Publication No. 2014-209270

### SUMMARY

A film formation method according to an aspect of the present disclosure includes: a) loading a substrate including a base film and a resist provided on the base film and having a predetermined pattern formed thereon into a chamber; b) supplying a gas of a first monomer into the chamber; c) supplying a purge gas into the chamber; d) supplying a gas of a second monomer into the chamber to form a polymer film on a surface of the substrate by a polymerization reaction between the first monomer and the second monomer; and e) supplying a purge gas into the chamber, wherein a vapor pressure ratio of the first monomer or the second monomer whichever has a lower saturated vapor pressure is 0.05 or less.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram showing an example of a processing apparatus.

FIG. 2 is a flowchart showing an example of a processing procedure for a substrate.

FIG. 3A is a schematic diagram showing an example of a process for forming a polymer film on a pattern having protrusions and recesses.

FIG. 3B is a schematic diagram showing an example of a process for forming a polymer film on a pattern having protrusions and recesses.

FIG. 4A is a schematic diagram showing an example of a process for forming a polymer film on a hole.

FIG. 4B is a schematic diagram showing an example of a process for forming a polymer film on a hole.

FIG. 5A is a schematic diagram showing an example of a process for forming a polymer film on two communicating holes.

FIG. 5B is a schematic diagram showing an example of a process for forming a polymer film on two communicating holes.

FIG. 6 is a diagram showing an example of a relationship between the number of times a film formation process is repeated and a change in a thickness of the polymer film.

FIG. 7A is a diagram showing an example of shapes of openings of holes before a polymer film is formed.

FIG. 7B is a diagram showing an example of shapes of openings of holes after a polymer film is formed.

FIG. 8A is a diagram showing an example of cross-sectional shapes of holes before a polymer film is formed.

FIG. 8B is a diagram showing an example of cross-sectional shapes of holes after a polymer film is formed.

FIG. 9A is a diagram showing an example of shapes of openings of holes before a polymer film is formed.

FIG. 9B is a diagram showing an example of shapes of openings of holes after a polymer film is formed.

FIG. 10A is a diagram showing an example of shapes of openings of holes before a polymer film is formed.

FIG. 10B is a diagram showing an example of shapes of openings of holes after a polymer film is formed.

FIG. 11A is a diagram showing an example of shapes of resist lines before a polymer film is formed.

FIG. 11B is a diagram showing an example of shapes of resist lines after a polymer film is formed.

FIG. 12A is a diagram showing an example of shapes of openings of holes in a resist on which a polymer film is not formed.

FIG. 12B is a diagram showing an example of shapes of openings of holes in a base film after etching is performed through a resist on which a polymer film is not formed.

FIG. 13A is a diagram showing an example of shapes of openings of holes in a resist on which a polymer film is formed.

FIG. 13B is a diagram showing an example of shapes of openings of holes in a base film after etching is performed through a resist on which a polymer film is formed.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a film formation method and a film formation apparatus will be described in detail with reference to the drawings. Note that the following embodiments do not limit the film formation method and the film formation apparatus disclosed herein.

With miniaturization of processes, control of a line width (CD: Critical Dimension) of a pattern formed on a substrate is becoming more important. In order to form a pattern having a desired CD on a substrate with high precision, further improvement in the precision of a CD of a pattern formed on a resist is required.

Therefore, the present disclosure provides a technique capable of improving a precision of a pattern formed on a substrate.

### [Configuration of Processing Apparatus 1]

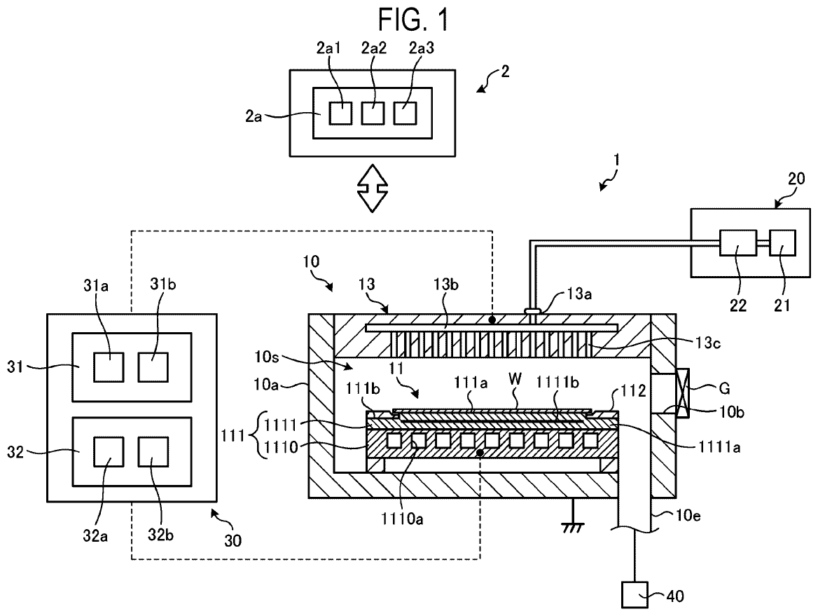

FIG. 1 is a schematic diagram showing an example of a processing apparatus 1. In the present embodiment, the processing apparatus 1 is, for example, a capacitively-coupled plasma processing apparatus. The processing apparatus 1 is an example of a film formation apparatus. The processing apparatus 1 includes a chamber 10, a gas supply 20, a power supply 30, and an exhaust system 40. The processing apparatus 1 further includes a substrate support 11 and a gas introduction part. The gas introduction part is configured to introduce at least one type of gas into the chamber 10. The gas introduction part includes a shower head 13. The substrate support 11 is arranged in the chamber 10. The shower head 13 is arranged above the substrate support 11. In one embodiment, the shower head 13 constitutes at least a part of a ceiling of the chamber 10. The chamber 10 has a processing space 10s defined by the shower head 13, a sidewall 10a of the chamber 10, and the substrate support 11.

The chamber 10 has at least one gas supply port configured to supply at least one type of gas to the processing space 10s and at least one gas exhaust port configured to exhaust the gas from a plasma processing space. The chamber 10 is made of a conductor such as aluminum and is grounded. The shower head 13 and the substrate support 11 are electrically insulated from the housing of the chamber 10. An opening 10b for loading and unloading a substrate W into and from the chamber 10 is formed at the sidewall 10a of the chamber 10. The opening 10b is opened and closed by a gate valve G.

The substrate support 11 includes a main body 111 and a ring assembly 112. The main body 111 has a central region 111a for supporting the substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is arranged on the base 1110. The electrostatic chuck 1111 includes a ceramic member 1111a and an electrostatic electrode 1111b arranged within the ceramic member 1111a. The ceramic member 1111a has a central region 111a. In one embodiment, the ceramic member 1111a also has an annular region 111b. Other members surrounding the electrostatic chuck 1111, such as an annular electrostatic chuck (not shown) or an annular insulating member (not shown), may have the annular region 111b. In this case, the ring assembly 112 may be arranged on the annular electrostatic chuck or the annular insulating member, or may be arranged on both the electrostatic chuck 1111 and the annular insulating member. In addition, at least one RF/DC electrode coupled to an RF (Radio Frequency) power supply 31 and/or a DC (Direct Current) power supply 32 described later may be arranged within the ceramic member 1111a. In this case, the at least one RF/DC electrode functions as a lower electrode. When a bias RF signal and/or a DC signal described later is supplied to the at least one RF/DC electrode, the RF/DC electrode is also called a bias electrode. Further, the conductive member of the base 1110 and the at least one RF/DC electrode may function as multiple lower electrodes. In addition, the electrostatic electrode 1111b may function as a lower electrode. Thus, the substrate support 11 includes at least one lower electrode.

The ring assembly 112 includes one or more annular members. In one embodiment, the one or more annular members include one or more edge rings and at least one cover ring. The edge rings are made of a conductive or insulating material, and the cover ring is made of an insulating material.

The substrate support 11 may also include a temperature adjustment module configured to adjust a temperature of at least one selected from the group of the electrostatic chuck 1111, the ring assembly 112, and the substrate W to a target temperature. The temperature adjustment module may include a heater, a heat transfer medium, a flow path 1110a, or a combination thereof. A heat transfer fluid such as brine or a gas flows through the flow path 1110a. In one embodiment, the flow path 1110a is formed in the base 1110, and one or more heaters are arranged in the ceramic member 1111a of the electrostatic chuck 1111. The substrate support 11 may also include a heat transfer medium supply configured to supply a heat transfer medium, such as a heat transfer gas, to a gap between a back surface of the substrate W and the central region 111a.

Through-holes (not shown) are formed in the electrostatic chuck 1111 below the central region 111a, and lift pins (not shown) are inserted into the through-holes. The lift pins are raised and lowered by a lifting mechanism (not shown). The lift pins are raised and lowered to raise and lower the substrate W placed on the central region 111a. For example, after the gate valve G is opened, the substrate W is loaded into the chamber 10 through the opening 10b by a transfer robot (not shown), and is placed on the lift pins whose tips protrude from the upper surface of the electrostatic chuck 1111. Then, the lift pins are lowered, such that the substrate W is placed on the electrostatic chuck 1111, the gate valve G is closed, and processing is performed on the substrate W in the chamber 10. In addition, the lift pins are raised, such that the processed substrate W is lifted from the upper surface of the electrostatic chuck 1111. Then, after the gate valve G is opened, the substrate W is unloaded from the chamber 10 through the opening 10b by the transfer robot (not shown).

The shower head 13 is configured to introduce at least one type of gas from the gas supply 20 into the processing space 10s. The shower head 13 includes at least one gas supply port 13a, at least one gas diffusion chamber 13b, and multiple gas introduction ports 13c. The gas supplied to the gas supply port 13a passes through the gas diffusion chamber 13b and is introduced into the processing space 10s from the multiple gas introduction ports 13c. The shower head 13 further includes at least one upper electrode (not shown). In addition to the shower head 13, the gas introduction part may include one or more side gas injectors (SGI) attached to one or more openings (not shown) formed at the sidewall 10a.

The gas supply 20 may include at least one gas source 21 and at least one flow rate controller 22. In one embodiment, the gas supply 20 is configured to supply at least one type of gas from each gas source 21 to the showerhead 13 through each flow rate controller 22. Each flow rate controller 22 may include, for example, a mass flow controller or a pressure-controlled flow rate controller. Additionally, the gas supply 20 may include one or more flow rate modulation devices configured to modulate or pulse the flow rate of the at least one type of gas.

The power supply 30 includes an RF power supply 31 coupled to the chamber 10 via at least one impedance matching circuit. The RF power supply 31 is configured to supply at least one RF signal (RF power) to at least one lower electrode and/or at least one upper electrode. Thus, plasma is formed from at least one type of gas supplied to the processing space 10s. Accordingly, the RF power supply 31 can function as at least a part of a plasma generating part configured to generate plasma from one or more types of gas in the chamber 10. In addition, by supplying a bias RF signal to the at least one lower electrode, a bias potential can be generated on the substrate W, and ion components in the formed plasma can be attracted to the substrate W.

In one embodiment, the RF power supply 31 includes a first RF generation part 31a and a second RF generation part 31b. The first RF generation part 31a is coupled to at least one lower electrode and/or at least one upper electrode via at least one impedance matching circuit and configured to generate a source RF signal (source RF power) for plasma generation. In one embodiment, the source RF signal has a frequency in the range of 10 MHz to 150 MHz. In one embodiment, the first RF generation part 31a may be configured to generate multiple source RF signals having different frequencies. The one or more source RF signals thus generated are supplied to at least one lower electrode and/or at least one upper electrode.

The second RF generation part 31b is coupled to at least one lower electrode via at least one impedance matching circuit and configured to generate a bias RF signal (bias RF power). A frequency of the bias RF signal may be the same as or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generation part 31b may be configured to generate multiple bias RF signals having different frequencies. The one or more bias RF signals thus generated are supplied to at least one lower electrode. In various embodiments, at least one selected from the group of the source RF signal and the bias RF signal may be pulsed.

The power supply 30 may further include a DC power supply 32 coupled to the chamber 10. The DC power supply 32 includes a first DC generation part 32a and a second DC generation part 32b. In one embodiment, the first DC generation part 32a is connected to the at least one lower electrode and configured to generate a first DC signal. The first bias DC signal thus generated is applied to the at least one lower electrode. In one embodiment, the second DC generation part 32b is connected to the at least one upper electrode and configured to generate a second DC signal. The second DC signal thus generated is applied to the at least one upper electrode.

In various embodiments, at least one selected from the group of the first DC signal and the second DC signal may be pulsed. In this case, a sequence of voltage pulses is applied to at least one lower electrode and/or at least one upper electrode. The voltage pulses may have a rectangular pulse waveform, a trapezoidal pulse waveform, a triangular pulse waveform, or a combination thereof. In one embodiment, a waveform generation part configured to generate a sequence of voltage pulses from the DC signal is connected between the first DC generation part 32a and at least one lower electrode. Thus, the first DC generation part 32a and the waveform generation part constitute a voltage pulse generation part. When the second DC generation part 32b and the waveform generation part constitute a voltage pulse generation part, the voltage pulse generation part is connected to at least one upper electrode. The voltage pulses may have a positive polarity or a negative polarity. Further, the sequence of voltage pulses may include one or more positive polarity voltage pulses and one or more negative polarity voltage pulses in one period. The first and second DC generation parts 32a and 32b may be provided in addition to the RF power supply 31, or the first DC generation part 32a may be provided in place of the second RF generation part 31b.

The exhaust system 40 may be connected to, for example, a gas exhaust port 10e provided at the bottom of the chamber 10. The exhaust system 40 may include a pressure regulation valve and a vacuum pump. The pressure in the processing space 10s is regulated by the pressure regulation valve. The vacuum pump may include a turbomolecular pump, a dry pump, or a combination thereof.

The controller 2 processes computer-executable instructions that cause each processing apparatus 1 to execute various steps described in the present disclosure. The controller 2 may be configured to control each element of the processing apparatus 1 to execute various steps described herein. In one embodiment, a part or the entirety of the controller 2 may be included in the processing apparatus 1. The controller 2 may include a processing part 2a1, a computer readable memory part 2a2, and a communication interface 2a3. The controller 2 is realized, for example, by a computer 2a. The processing part 2al may be configured to perform various control operations by reading a program from the memory part 2a2 and executing the read program. This program may be stored in the memory part 2a2 in advance, or may be acquired via a medium when necessary. The acquired program is stored in the memory part 2a2. The program is read from the memory part 2a2 and executed by the processing part 2al. The medium may be various storage media readable by the computer 2a, or may be a communication line connected to the communication interface 2a3. The processing part 2al may be a CPU (Central Processing Unit). The memory part 2a2 may include a random access memory (RAM), a read only memory (ROM), a hard disk drive (HDD), a solid state drive (SSD), or a combination thereof. The communication interface 2a3 communicates with the processing apparatus 1 via a communication line such as a local area network (LAN) or the like.

### [Processing Procedure for Substrate W]

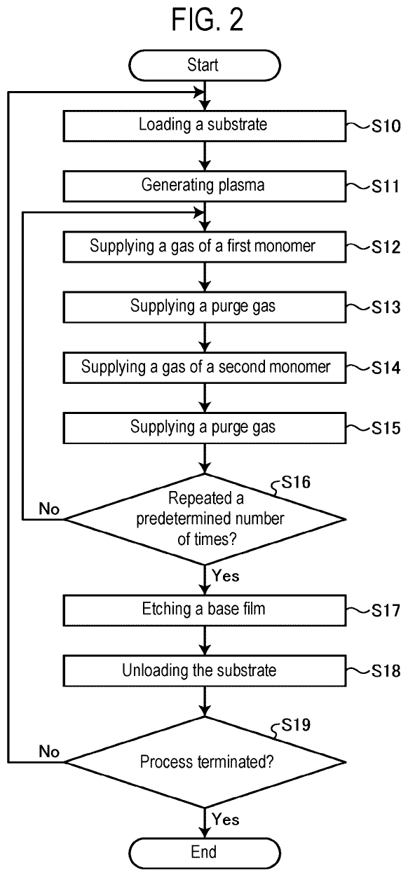

FIG. 2 is a flowchart showing an example of a processing procedure for a substrate W. Each process illustrated in FIG. 2 is realized when the controller 2 controls each part of the processing apparatus 1. The processing procedure illustrated in FIG. 2 is an example of a film formation method.

First, the substrate W is loaded into the chamber 10 (step S10). Step S10 is an example of process a). In the present embodiment, the substrate W includes a base film and a resist provided on the base film and having a predetermined pattern formed thereon. In step S10, the controller 2 controls a drive mechanism for the lift pins (not shown) so that tips of the lift pins (not shown) protrude from the upper surface of the electrostatic chuck 1111. Then, the controller 2 controls the gate valve G so as to open the gate valve G. The substrate W is loaded into the chamber 10 by the transfer robot (not shown) through the opening 10b and placed on the lift pins. Then, the controller 2 controls the drive mechanism for the lift pins so that the lift pins are lowered. As a result, the lift pins are lowered and the substrate W is placed on the electrostatic chuck 1111. Then, the controller 2 controls the gate valve G so as to close the gate valve G.

Next, plasma is generated in the chamber 10 (step S11). Step S11 is an example of process f). In step S11, an oxygen gas is supplied from the gas supply 20 into the chamber 10 via the shower head 13. The oxygen gas is converted into plasma by RF power supplied from the power supply 30 into the chamber 10. Then, oxygen radicals contained in the plasma modify the surface of the substrate W (e.g., the surface of the resist) into a hydrophilic surface. This makes it easier for molecules of a monomer to be adsorbed on the surface of the substrate W.

The gas used to generate the plasma is not limited to the oxygen gas, as long as it is an oxygen-containing gas. Examples of the oxygen-containing gas include H₂O, NO, N₂O, CO₂, and H₂O₂. Another method for modifying the surface of the substrate into the hydrophilic surface is to expose the surface of the substrate to an atmosphere after plasma processing is performed by using a hydrogen-containing gas, an argon gas, or the like.

Next, a gas of a first monomer is supplied into the chamber 10 (step S12). Step S12 is an example of process b). In the present embodiment, the first monomer is, for example, isocyanate. In step S12, the gas of the first monomer is supplied from the gas supply 20 into the chamber 10 via the shower head 13. The molecules of the first monomer contained in the gas supplied into the chamber 10 are adsorbed on the surface of the substrate W. Step S12 is performed for, for example, 4 seconds.

Next, a purge gas is supplied into the chamber 10 (step S13). Step S13 is an example of process c). In the present embodiment, the purge gas is an inert gas such as a nitrogen gas or a rare gas. In step S13, the purge gas is supplied into the chamber 10 from the gas supply 20 via the shower head 13. The purge gas supplied into the chamber 10 purges molecules of the first monomer excessively adsorbed on the surface of the substrate W. Step S13 is performed for, for example, 4 seconds.

Next, a gas of a second monomer is supplied into the chamber 10 (step S14). Step S14 is an example of process d). In the present embodiment, the second monomer is, for example, amine. In step S14, the gas of the second monomer is supplied from the gas supply 20 into the chamber 10 via the shower head 13. The molecules of the second monomer contained in the gas supplied into the chamber 10 undergo a polymerization reaction with the molecules of the first monomer adsorbed on the surface of the substrate W. Then, a polymer film having urea bonds is formed on the surface of the substrate W by the polymerization reaction between the molecules of the first monomer and the molecules of the second monomer. Step S14 is performed for, for example, 4 seconds.

Next, a purge gas is supplied into the chamber 10 (step S15). Step S15 is an example of process e). In step S15, a purge gas is supplied into the chamber 10 from the gas supply 20 via the shower head 13. The purge gas supplied into the chamber 10 purges molecules of the second monomer excessively adsorbed on the surface of the substrate W. Step S15 is performed for, for example, 4 seconds.

Next, the controller 2 determines whether the processes of steps S12 to S15 have been repeated a predetermined number of times (step S16). Hereinafter, the processes of steps S12 to S15 will be referred to as a film formation process. If the film formation process has not been repeated a predetermined number of times (step S16: No), the controller 2 executes the process shown in step S12 again. The predetermined number of times refers to the number of times the film formation process is repeated until a polymer film having a desired thickness is formed on the surface of the substrate W. In the present embodiment, the desired thickness of the polymer film is, for example, 1 nm to 2.5 nm. The predetermined number of times may be one time.

In some cases, the resist provided on the substrate W may be altered at a temperature of 130 degrees C. or higher. Furthermore, a temperature equal to or higher than the room temperature is necessary for the first monomer and the second monomer to undergo a polymerization reaction. Therefore, the temperature of the substrate W during the film formation process is preferably maintained within a range of, for example, 20 degrees C. or higher and 120 degrees C. or lower.

When the film formation process is repeated a predetermined number of times (step S16: Yes), the base film is etched (step S17). In step S17, an etching gas is supplied from the gas supply 20 into the chamber 10 via the shower head 13. In the present embodiment, the base film is, for example, a silicon oxide film, and the etching gas is, for example, a fluorine-containing gas. Then, RF power for plasma generation is supplied from the power supply 30 into the chamber 10, and the etching gas is converted into plasma in the chamber 10. In addition, RF power and a DC signal for bias are supplied from the power supply 30 into the chamber 10 as necessary. Then, the base film is etched along the pattern formed in the resist by active species, ions, or the like contained in the plasma.

Next, the substrate W is unloaded from the chamber 10 (step S18). In step S18, the controller 2 controls the drive mechanism for the lift pins so that the tips of the lift pins protrude from the upper surface of the electrostatic chuck 1111. This causes the processed substrate W to be raised from the electrostatic chuck 1111. Then, the controller 2 controls the gate valve G to open the gate valve G. The processed substrate W is unloaded from the chamber 10 by the transfer robot (not shown) through the opening 10b. Then, the controller 2 controls the gate valve G to close the gate valve G, and controls the drive mechanism for the lift pins so that the lift pins are lowered.

Next, the controller 2 determines whether or not to terminate the processing of the substrate W (step S19). If the processing of the substrate W is not to be terminated (step S19: No), the controller 2 executes the processing shown in step S10 again. On the other hand, if the processing of the substrate W is to be terminated (step S19: Yes), the controller 2 terminates the processing procedure for the substrate W shown in the flowchart. In the above processing procedure for the substrate W, the example in which steps S11 to S17 are performed by one processing apparatus has been described. However, the present disclosure is not limited thereto. As another example, step S11, steps S12 to S16, and step S17 may be performed by separate apparatuses, respectively.

### [Polymer Film Formation Process]

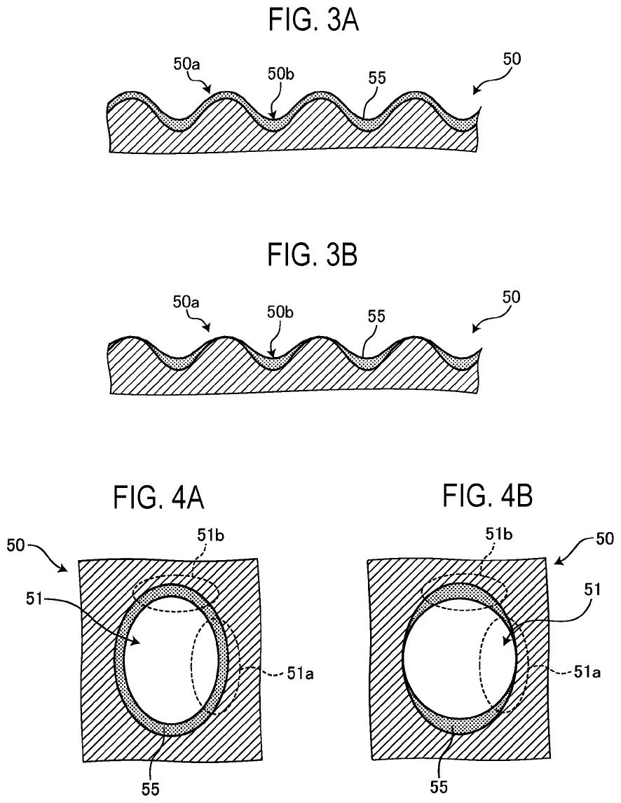

FIGS. 3A and 3B are schematic diagrams showing an example of a process for forming a polymer film on a pattern with protrusions and recesses. On the surface of the resist 50, as shown in FIGS. 3A and 3B, there are protrusions 50a and recesses 50b due to a surface roughness of the resist 50. Although FIGS. 3A and 3B show an example of the protrusions 50a and recesses 50b on the upper surface of the resist 50, a side surface of the resist 50 also has the same protrusions 50a and recesses 50b as those in FIGS. 3A and 3B.

When the gas of the first monomer is supplied in step S12 of FIG. 2, the molecules of the first monomer are adsorbed along the surface of the resist 50. That is, as shown in FIG. 3A, for example, the molecules 55 of the first monomer are adsorbed to the protrusions 50a and the recesses 50b on the surface of the resist 50 with approximately the same thickness.

When the purge gas is supplied in step S13 of FIG. 2, the molecules 55 of the first monomer that are excessively adsorbed on the surface of the resist 50 are purged. At this time, as shown in FIG. 3B, for example, the molecules 55 of the first monomer adsorbed on the protrusions 50a are purged more than the molecules 55 of the first monomer adsorbed on the recesses 50b.

When the gas of the second monomer is supplied in step S14 of FIG. 2, the molecules of the second monomer are adsorbed along the surface of the resist 50 on which the molecules of the first monomer are adsorbed. Then, a polymer film having urea bonds is formed on the surface of the resist 50 by a polymerization reaction between the molecules of the first monomer and the molecules of the second monomer.

At this time, as shown in FIG. 3B, for example, the number of the molecules 55 of the first monomer adsorbed on the protrusions 50a is smaller than the number of the molecules 55 of the first monomer adsorbed on the recesses 50b. On the other hand, the number of the molecules 55 of the first monomer adsorbed on the recesses 50b is greater than the number of the molecules 55 of the first monomer adsorbed on the protrusions 50a. Therefore, the thickness of the polymer film formed by the polymerization reaction with the molecules of the second monomer is thicker on the recesses 50b than on the protrusions 50a. As a result, a difference in height between the protrusions 50a and the recesses 50b after the polymer film is formed is smaller than a difference in height between the protrusions 50a and the recesses 50b before the polymer film is formed. Accordingly, the surface roughness of the resist 50 after the polymer film is formed is less than the surface roughness of the resist 50 before the polymer film is formed. This makes it possible to reduce a difference between the pattern formed on the resist 50 and the desired pattern. Then, by etching the base film below the resist 50 through the resist 50 after the polymer film has been formed, it is possible to improve the precision of the pattern formed in the base film.

FIGS. 4A and 4B are schematic diagrams showing an example of a process for forming a polymer film in a hole. As shown in FIGS. 4A and 4B, for example, a hole 51 is formed in the resist 50. However, a shape of the hole 51 may be an oval shape, which is different from a perfect circle, due to the surface roughness of the resist 50.

When the gas of the first monomer is supplied in step S12 of FIG. 2, the molecules of the first monomer are adsorbed along the surface of the resist 50. That is, for example, as shown in FIG. 4A, the molecules 55 of the first monomer are adsorbed along the inner wall of the hole 51.

When the purge gas is supplied in step S13 of FIG. 2, the molecules 55 of the first monomer excessively adsorbed on the inner wall of the hole 51 are purged. In this case, as shown in FIG. 4B, for example, in the oval hole 51, the molecules 55 of the first monomer adsorbed on an inner wall portion 51a having a small curvature are purged more than the molecules 55 of the first monomer adsorbed on an inner wall portion 51b having a large curvature.

When the gas of the second monomer is supplied in step S14 of FIG. 2, the molecules of the second monomer are adsorbed along the inner wall of the hole 51 on which the molecules of the first monomer are adsorbed. Then, a polymer film having urea bonds is formed on the surface of the resist 50 by a polymerization reaction between the molecules of the first monomer and the molecules of the second monomer.

At this time, as shown in FIG. 4B, for example, the number of the molecules 55 of the first monomer adsorbed on the inner wall portion 51a with a small curvature is smaller than the number of the molecules 55 of the first monomer adsorbed on the inner wall portion 51b with a large curvature. On the other hand, the number of the molecules 55 of the first monomer adsorbed on the inner wall portion 51b with the large curvature is greater than the number of the molecules 55 of the first monomer adsorbed on the inner wall portion 51a with the small curvature. Therefore, the thickness of the polymer film formed by the polymerization reaction with the molecules of the second monomer is greater on the inner wall portion 51b with the large curvature than on the inner wall portion 51a with the small curvature. As a result, the shape of the hole 51 after the polymer film is formed is closer to a perfect circle than the shape of the hole 51 before the polymer film is formed. As a result, the shape of the hole 51 can be made closer to a desired shape. Then, by etching the base film below the resist 50 through the hole 51 after the polymer film is formed, it is possible to improve the precision of the shape of the hole formed in the base film.

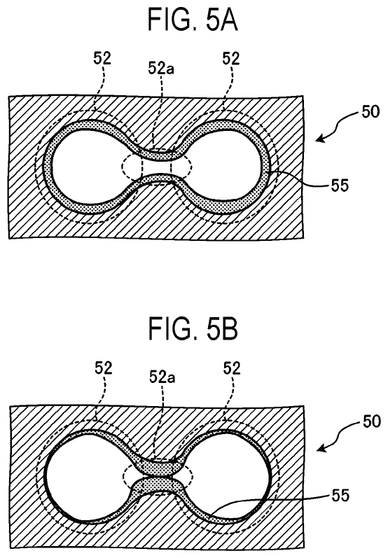

FIGS. 5A and 5B are schematic diagrams showing an example of a process for forming a polymer film in two communicating holes. In the resist 50, holes 52 are formed adjacent to each other, for example, as shown in FIGS. 5A and 5B. However, the two adjacent holes 52 may have a shape different from a perfect circle due to the surface roughness of the resist 50, and the adjacent holes 52 may communicate with each other at a communicating portion 52a therebetween, which is called a kissing defect.

When the gas of the first monomer is supplied in step S12 of FIG. 2, the molecules of the first monomer are adsorbed along the surface of the resist 50. That is, for example, as shown in FIG. 5A, the molecules 55 of the first monomer are adsorbed along the inner walls of the two holes 52 and the inner wall of the communicating portion 52a.

When the purge gas is supplied in step S13 of FIG. 2, the molecules 55 of the first monomer excessively adsorbed on the inner walls of the holes 52 and the communicating portion 52a are purged. In this case, as shown in FIG. 5B, for example, the molecules 55 of the first monomer adsorbed on the inner walls of the holes 52 are purged more than the molecules 55 of the first monomer adsorbed on the inner wall of the communicating portion 52a.

When the gas of the second monomer is supplied in step S14 of FIG. 2, the molecules of the second monomer are adsorbed along the inner walls of the holes 52 and the communicating portion 52a on which the molecules of the first monomer are adsorbed. Then, a polymer film having urea bonds is formed on the surface of the resist 50 by a polymerization reaction between the molecules of the first monomer and the molecules of the second monomer.

At this time, as shown in FIG. 5B, for example, the number of the molecules 55 of the first monomer adsorbed on the inner wall of the hole 52 is smaller than the number of the molecules 55 of the first monomer adsorbed on the inner wall of the communicating portion 52a. On the other hand, the number of the molecules 55 of the first monomer adsorbed on the inner wall of the communicating portion 52a is greater than the number of the molecules 55 of the first monomer adsorbed on the inner wall of the hole 52. Therefore, the polymer film formed by the polymerization reaction with the molecules of the second monomer is thicker on the inner wall of the communicating portion 52a than on the inner wall of the hole 52. Thus, the communicating portion 52a is blocked by the polymer film. As a result, the two adjacent holes 52 can be made into independent holes 52 that are not connected to each other. Then, the base film below the resist 50 is etched through the hole 52 after the polymer film is formed, thereby improving the precision of the shape of the hole formed in the base film.

[Relationship between Film Thickness and Vapor Pressure Ratio]

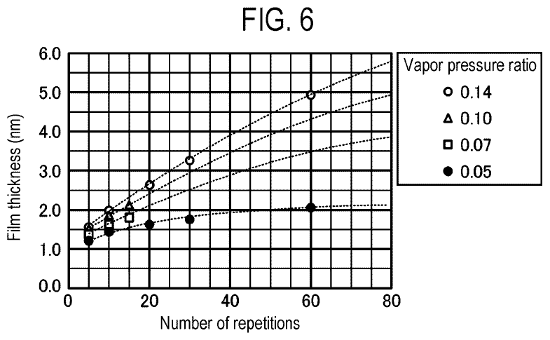

FIG. 6 is a diagram showing an example of a relationship between the number of times the film formation process is repeated and the change in the thickness of the polymer film. In FIG. 6, experiments were performed for different vapor pressure ratios for the first monomer or the second monomer, whichever has a lower saturated vapor pressure. In the present embodiment, the first monomer is isocyanate, and the second monomer is amine. The isocyanate has a lower saturated vapor pressure than the amine. Therefore, FIG. 6 shows the vapor pressure ratio for isocyanate.

The vapor pressure ratio Pr is expressed by the following formula (1), where P1 is a partial pressure of a monomer gas and P0 is a saturated vapor pressure of the monomer gas.

Pr=P1/P0 (1)

For example, as shown in FIG. 6, as the vapor pressure ratio becomes higher, a rate of increase in the thickness of the polymer film with respect to the number of times of the film formation process becomes greater. As the vapor pressure ratio becomes lower, the rate of increase in the thickness of the polymer film with respect to the number of times of the film formation process.

In a case where forming a pattern of several tens of nm or less, when the polymer film formed on the resist is too thick, the pattern may be filled with the polymer film. Further, if the polymer film formed on the resist is too thin, the precision of the resist pattern may not be improved sufficiently, and the precision of the pattern formed on the substrate by using the resist may also be insufficient. Therefore, the thickness of the polymer film formed on the resist is preferably within the range of 1 nm to 2.5 nm.

Referring to FIG. 6, when the vapor pressure ratio is 0.07 or more, the thickness of the polymer film may increase according to the number of times the film formation process is repeated, and may reach 2.5 nm or more. On the other hand, when the vapor pressure ratio is 0.05, the thickness of the polymer film increases according to the number of times the film formation process is repeated, but the increase in film thickness is gentle and the film thickness reaches about 2.0 nm. From the tendency shown in FIG. 6, it is considered that when the vapor pressure ratio is lower than 0.05, the thickness of the polymer film is in the range of 1 nm to 2 nm. If the change in the thickness of the polymer film can be suppressed within the range of 1 nm to 2.5 nm, the polymer film can be easily formed to have a thickness in a preferred range. Accordingly, in order to form a polymer film having a thickness in a preferred range in the present embodiment, it is preferable that the vapor pressure ratio is 0.05 or less.

### Experimental Results

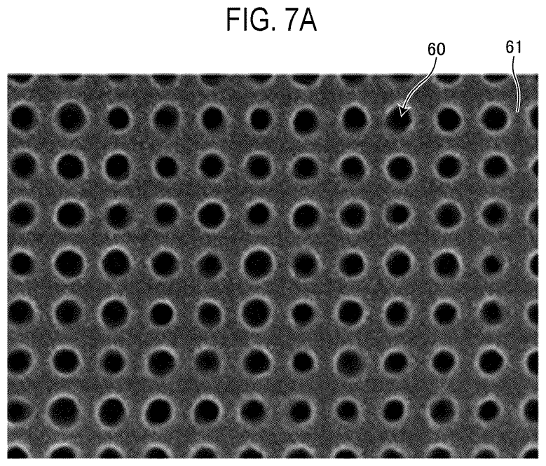

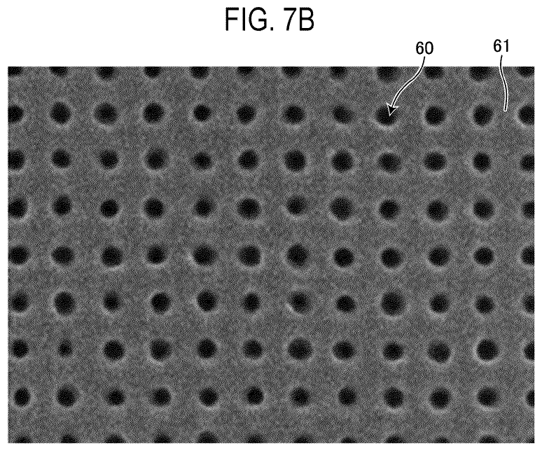

FIG. 7A shows an example of the shapes of the openings of the holes 60 before a polymer film is formed. In FIG. 7A, a plurality of holes 60 are formed in the resist 61. In FIG. 7A, an average CD of the openings of the holes 60 is 16.6 nm, and a local critical dimension uniformity (LCDU) is 4.5 nm.

On the other hand, when a polymer film having a thickness of 2 nm is formed on the resist 61 shown in FIG. 7A, a state of the holes 60 becomes, for example, a state shown in FIG. 7B. FIG. 7B is a diagram showing an example of the shapes of the openings of the holes 60 after the polymer film is formed. In FIG. 7B, the average CD of the openings of the holes 60 is 12.9 nm, and the LCDU is 3.3 nm. Comparing FIG. 7A with FIG. 7B, the LCDU of the opening of the hole 60 is improved by about 22%.

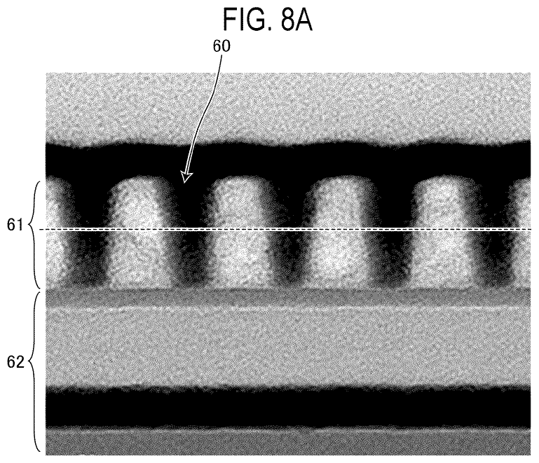

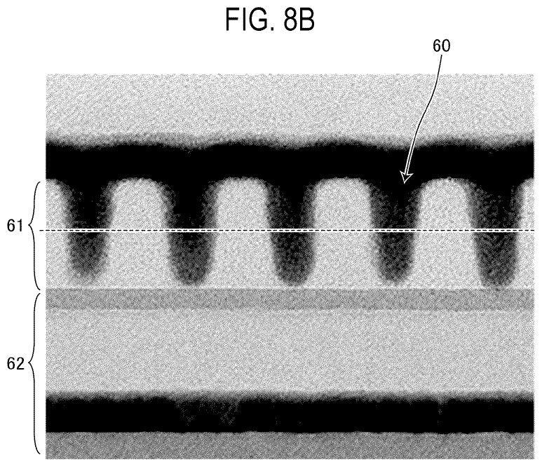

FIG. 8A is a diagram showing an example of the cross-sectional shapes of the holes 60 before a polymer film is formed. In FIG. 8A, a plurality of holes 60 are formed in the resist 61 laminated on the base film 62. In FIG. 8A, an average height of the resist 61 is 39.0 nm, and the average CD of the openings of the holes 60 is 16.9 nm.

On the other hand, when a polymer film having a thickness of 2 nm is formed on the resist 61 shown in FIG. 8A, the state of the hole 60 becomes, for example, a state shown in FIG. 8B. FIG. 8B is a diagram showing an example of the cross-sectional shapes of the hole 60 after the polymer film is formed. In FIG. 8B, the average height of the resist 61 is 39.2 nm, and the average CD of the openings of the holes 60 is 16.0 nm. A polymer film is also formed inside the hole 60, and it is considered that the LCDU is improved not only at the opening of the hole 60 but also inside the hole 60. In FIGS. 8A and 8B, a width of the hole 60 at the position indicated by the dashed line is measured as the CD.

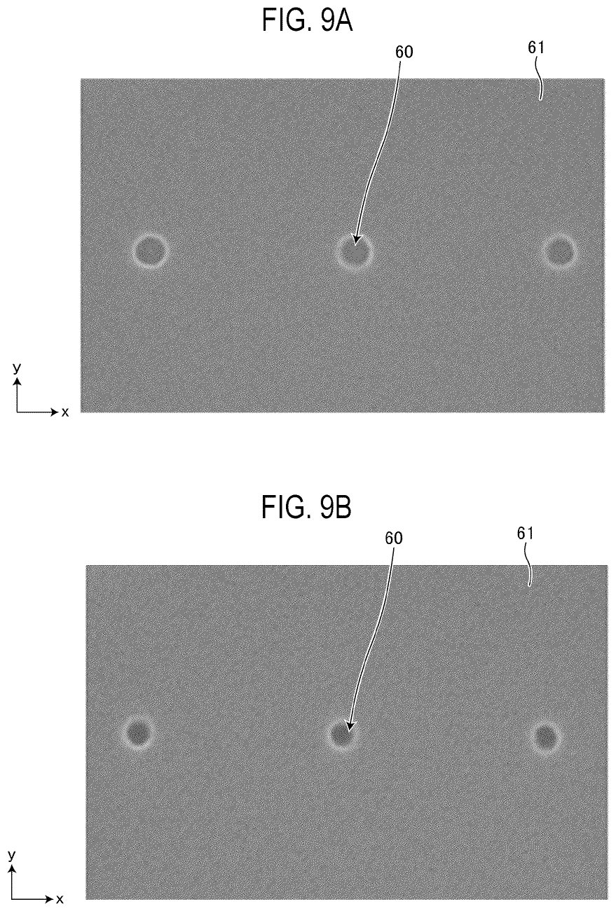

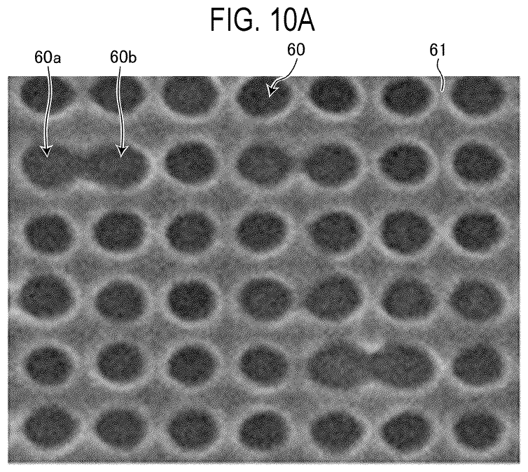

FIG. 9A is a diagram showing an example of the shapes of the openings of the holes before a polymer film is formed. In FIG. 9A, a plurality of holes 60 are formed in the resist 61, and an interval between adjacent holes 60 is wider than that in FIG. 7A. In FIG. 9A, the average CD of the openings of the holes 60 in the x direction is 33.0 nm, and the average CD in the y direction is 32.2 nm. The LCDU is 3.5 nm.

On the other hand, when a polymer film having a thickness of 2.5 nm is formed on the resist 61 shown in FIG. 9A, the state of the hole 60 becomes, for example, a state shown in FIG. 9B. FIG. 9B is a diagram showing an example of the shapes of the opening of the hole after the polymer film is formed. In FIG. 9B, the average CD of the openings of the hole 60 in the x direction is 25.4 nm, and the average CD in the y direction is 26.3 nm. The LCDU is 1.5 nm. Comparing FIG. 9A with FIG. 9B, the LCDU of the opening of the hole 60 is improved by about 57%.

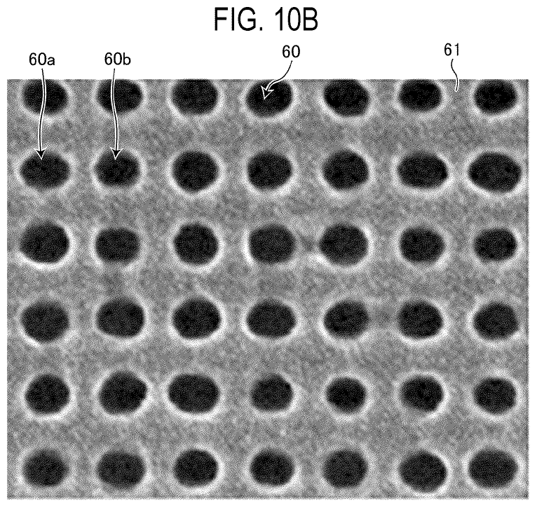

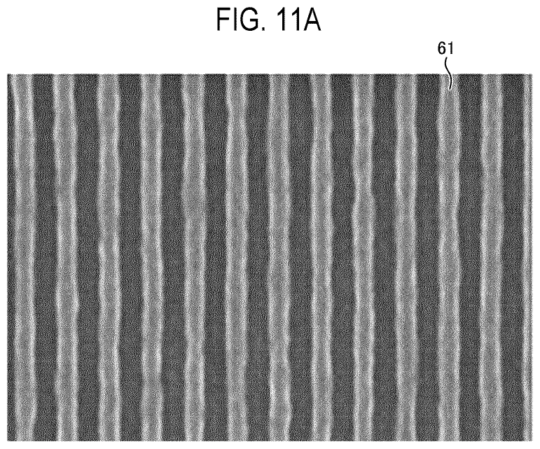

FIG. 10A is a diagram showing an example of the shapes of the openings of the holes before a polymer film is formed. In FIG. 10A, a plurality of holes 60 are formed in the resist 61, and some of the adjacent holes 60 (e.g., holes 60a and 60b) communicate with each other.

On the other hand, when a polymer film having a thickness of 2.5 nm is formed on the resist 61 shown in FIG. 10A, the state of the hole 60 becomes, for example, a state shown in FIG. 10B. FIG. 10B is a diagram showing an example of the shape of the opening of the hole after the polymer film is formed. Some of the holes 60 (e.g., holes 60a and 60b) communicating with each other in FIG. 10A are not in communication with each other in FIG. 10B, and each of them forms an independent hole 60, respectively. Comparing FIG. 10A with FIG. 10B, kissing defects in the plurality of holes 60 are improved.

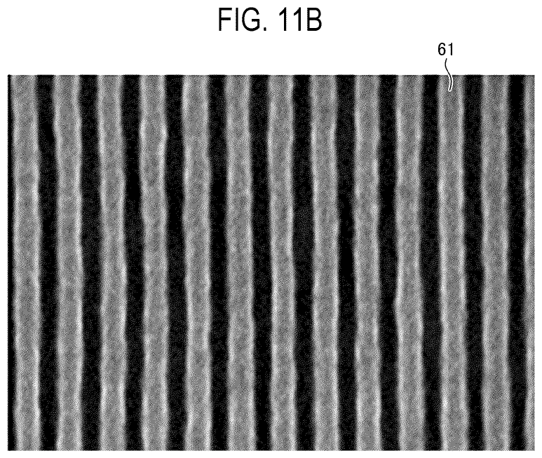

FIG. 11A is a diagram showing an example of a line shape of the resist 61 before a polymer film is formed. In FIG. 11A, a plurality of line-shaped patterns are formed in the resist 61. In FIG. 11A, the average CD of the CDs of the lines of the resist 61 is 17.1 nm, and a line edge roughness (LER) is 2.14 nm.

On the other hand, when a polymer film having a thickness of 2.5 nm is formed on the resist 61 shown in FIG. 11A, the state of the resist 61 becomes, for example, a state shown in FIG. 11B. FIG. 11B is a diagram showing an example of the line shape of the resist 61 after the polymer film is formed. In FIG. 11B, the average CD of the lines of the resist 61 is 20.5 nm, and the LER is 1.68 nm. Comparing FIG. 11A with FIG. 11B, the LER is improved by about 21%.

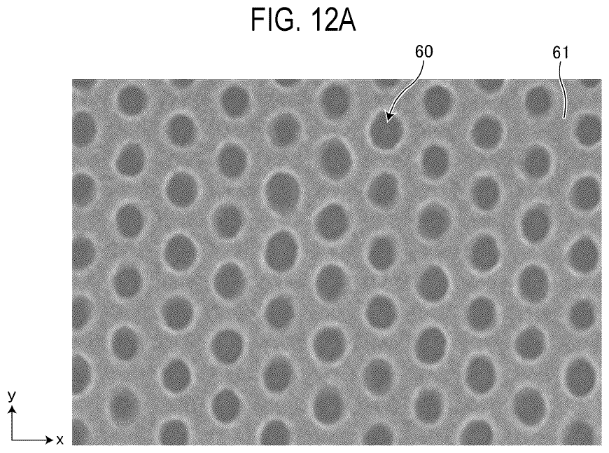

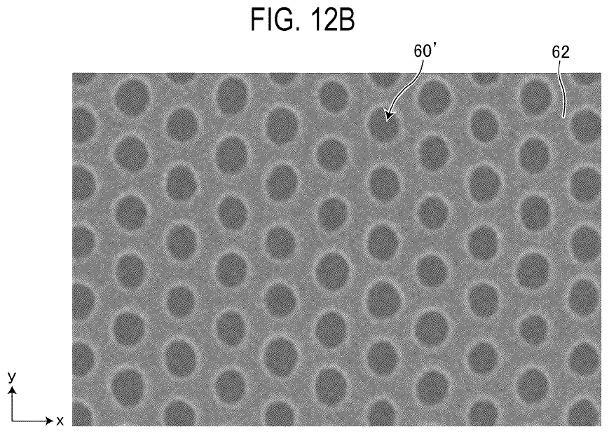

FIG. 12A is a diagram showing an example of the shape of the opening of the hole 60 in the resist 61 on which a polymer film is not formed. In FIG. 12A, a plurality of holes 60 are formed in the resist 61, and the opening of each hole 60 has an oval shape. In FIG. 12A, an average value of differences between the CD in the x direction and the CD in the y direction of the openings of the holes 60 is 4.2 nm.

FIG. 12B is a diagram showing an example of the shape of the openings of the holes in the base film after etching is performed through the resist 61 on which no polymer film is formed. When the base film 62 is etched through the resist 61 shown in FIG. 12A, for example, holes 60′ as shown in FIG. 12B are formed in the base film 62. Since the shape of the holes 60 shown in FIG. 12A is transferred to the base film 62, oval holes 60′ are formed in the base film 62. In FIG. 12B, an average value of differences between the CD in the x direction and the CD in the y direction of the openings of the holes 60′ is 3.1 nm.

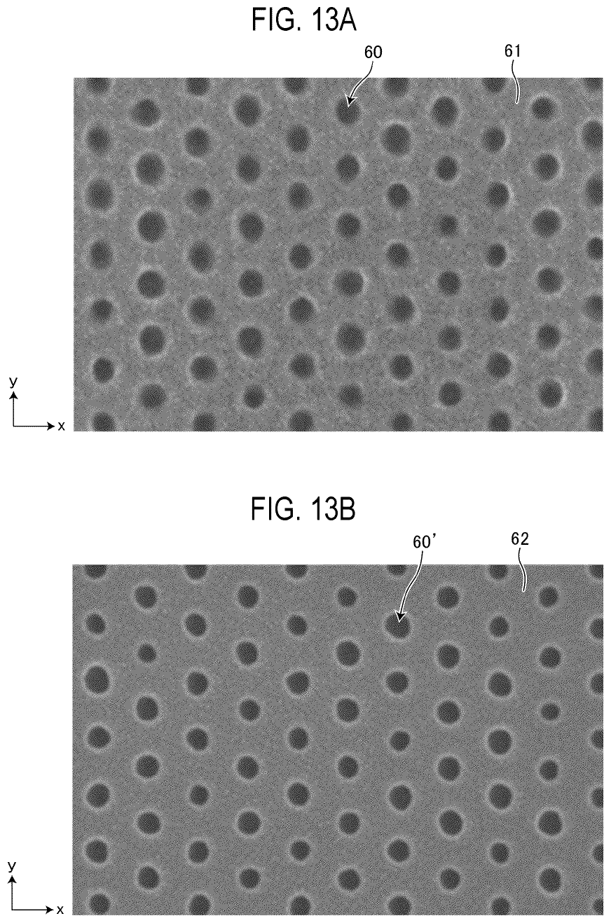

FIG. 13A is a diagram showing an example of the shape of the openings of the holes 60 in the resist 61 on which a polymer film is formed. In FIG. 13A, a polymer film having a thickness of 2 nm is formed on the resist 61. As a result, the opening of each hole 60 has a shape closer to a perfect circle than the hole 60 shown in FIG. 12A. In FIG. 13A, an average value of differences between the CD in the x direction and the CD in the y direction of the openings of the holes 60 is 1.6 nm. Comparing FIG. 12A with FIG. 13A, the average value of the differences between the CD in the x direction and the CD in the y direction of the openings of the holes 60 is improved by about 62%.

FIG. 13B is a diagram showing an example of the shape of the openings of the holes in the base film after etching is performed through the resist 61 on which a polymer film is formed. When the base film 62 is etched through the resist 61 shown in FIG. 13A, for example, holes 60′ as shown in FIG. 13B are formed in the base film 62. Since the shape of the holes 60 shown in FIG. 13A is transferred to the base film 62, holes 60′ including an opening having a shape closer to a perfect circle than the holes 60′ shown in FIG. 12B are formed in the base film 62. In FIG. 13B, an average value of differences between the CD in the x direction and the CD in the y direction of the openings of the holes 60′ is 1.2 nm. Comparing FIG. 12B with FIG. 13B, the average value of the differences between the CD in the x direction and the CD in the y direction of the openings of the holes 60 is improved by about 61%.

The embodiments has been described above. As described above, the film formation method according to the embodiments includes processes a), b), c), d), and e). In process a), a substrate (substrate W) including a base film (base film 62) and a resist (resist 50 or resist 61) provided on the base film and having a predetermined pattern formed thereon is loaded into a chamber (chamber 10). In step b), a gas of a first monomer is supplied into the chamber. In step c), a purge gas is supplied into the chamber. In step d), a gas of a second monomer is supplied into the chamber to form a polymer film on a surface of the substrate by a polymerization reaction between the first monomer and the second monomer. In step e), a purge gas is supplied into the chamber. In addition, a vapor pressure ratio of the first monomer or the second monomer whichever has a lower saturated vapor pressure is 0.05 or less. This can improve the precision of the pattern formed on the substrate.

In the above-described embodiments, processes b), c), d), and e) may be repeated multiple times in the named order. By controlling the number of repetitions, a polymer film having a desired thickness can be easily formed on the surface of the substrate.

The film formation method of the above-described embodiments may further include process f). The process f) is performed before process b) to supply an oxygen gas into the chamber and convert the oxygen gas in the chamber into plasma. This makes it possible to efficiently form a polymer film on the resist.

In the above-described embodiments, the substrate is maintained at a temperature in a range of 20 degrees C. or higher and 120 degrees C. or lower in processes b), c), d), and e). This makes it possible to form the polymer film by the polymerization reaction between the first monomer and the second monomer while preventing degradation of the resist.

In the above-described embodiments, the first monomer is isocyanate, the second monomer is amine, and the polymer film formed on the substrate contains urea bonds. This makes it possible to easily form the polymer film that can improve the precision of the pattern formed on the substrate.

The film formation apparatus (processing apparatus 1) in the above-described embodiments includes a chamber (chamber 10) including a gas supply port (gas supply port 13a) and a gas exhaust port (gas exhaust port 10e), a substrate support (substrate support 11) provided in the chamber and configured to support a substrate (substrate W) including a base film (base film 62) and a resist (resist 50 or resist 61) provided on the base film and having a predetermined pattern formed thereon, a lifting mechanism configured to raise and lower lift pins configured to support the substrate, a gas supply (gas supply 20) configured to supply a gas into the chamber, and a controller (controller 2). The controller is configured to perform processes a), b), c), d), and e). In process a), the controller controls the lifting mechanism to place the substrate loaded into the chamber on the substrate support via the lift pins. In process b), the controller controls the gas supply to supply a gas of a first monomer into the chamber. In process c), the controller controls the gas supply to supply a purge gas into the chamber. In process d), the controller controls the gas supply to supply a gas of a second monomer into the chamber to form a polymer film on a surface of the substrate by a polymerization reaction between the first monomer and the second monomer. In step e), the controller controls the gas supply to supply a purge gas into the chamber. In addition, a vapor pressure ratio of the first monomer or the second monomer whichever has a lower saturated vapor pressure is 0.05 or less. This can improve the precision of the pattern formed on the substrate.

### Others

The features disclosed in the present disclosure is not limited to the above-described embodiments, and various modifications may be made within the scope of the gist.

For example, in the above-described embodiments, a polymer film having urea bonds (—NH—CO—NH—) is formed on the surface of the substrate W by using isocyanate as the first monomer and amine as the second monomer. However, the present disclosure is not limited thereto. For example, a polymer film having imide bonds (—CO—N(—)—CO—) may be formed on the surface of the substrate W by using carboxylic anhydride as the first monomer and amine as the second monomer. Alternatively, a polymer film having 2-aminoethanol bonds (—NH—CH₂—CH(OH)—) may be formed on the surface of the substrate W by using epoxide as the first monomer and amine as the second monomer. Alternatively, a polymer film having urethane bonds (—NH—CO—O—) may be formed on the surface of the substrate W by using isocyanate as the first monomer and alcohol as the second monomer. Alternatively, a polymer film having amide bonds (—NH—CO—) may be formed on the surface of the substrate W by using acyl halide as the first monomer and amine as the second monomer.

In the above-described embodiments, the processing apparatus 1 is described which performs processing by using the capacitively-coupled plasma (CCP) as an example of a plasma source. However, the plasma source is not limited to the capacitively-coupled plasma. Examples of plasma sources other than the capacitively-coupled plasma may include inductively-coupled plasma (ICP), microwave-excited surface wave plasma (SWP), electron cyclotron resonance plasma (ECP), and helicon wave-excited plasma (HWP).

In addition, the embodiments disclosed herein should be considered to be exemplary and not limitative in all respects. Indeed, the above-described embodiments may be embodied in various forms. In addition, the above-described embodiments may be omitted, substituted, or modified in various forms without departing from the scope and spirit of the appended claims.

Furthermore, the following supplementary notes are disclosed regarding the above-described embodiments.

### Supplementary Note 1

A film formation method, includes:
a) loading a substrate including a base film and a resist provided on the base film and having a predetermined pattern formed thereon into a chamber;
b) supplying a gas of a first monomer into the chamber;
c) supplying a purge gas into the chamber;
d) supplying a gas of a second monomer into the chamber to form a polymer film on a surface of the substrate by a polymerization reaction between the first monomer and the second monomer; and
e) supplying a purge gas into the chamber,
wherein a vapor pressure ratio of the first monomer or the second monomer whichever has a lower saturated vapor pressure is 0.05 or less.

### Supplementary Note 2

The film formation method of Supplementary Note 1, wherein b), c), d), and e) are repeated multiple times in the named order.

### Supplementary Note 3

The film formation method of Supplementary Note 1 or 2, further including:
f) before b), supplying an oxygen-containing gas into the chamber and converting the oxygen-containing gas in the chamber into plasma.

### Supplementary Note 4

The film formation method of any one of Supplementary Notes 1 to 3, wherein in b), c), d), and e), the substrate is maintained at a temperature in a range of 20 degrees C. or higher and 120 degrees C. or lower.

### Supplementary Note 5

The film formation method of any one of Supplementary Notes 1 to 4, wherein the first monomer is isocyanate, the second monomer is amine, and the polymer film formed on the substrate contains urea bonds.

### Supplementary Note 6

The film formation method of any one of Supplementary Notes 1 to 4, wherein the first monomer is carboxylic acid anhydride, the second monomer is amine, and the polymer film formed on the substrate contains imide bonds.

### Supplementary Note 7

The film formation method of any one of Supplementary Notes 1 to 4, wherein the first monomer is epoxide, the second monomer is amine, and the polymer film formed on the substrate contains 2-aminoethanol bonds.

### Supplementary Note 8

The film formation method any one of claims 1 to 4, wherein the first monomer is isocyanate, the second monomer is alcohol, and the polymer film formed on the substrate contains urethane bonds.

### Supplementary Note 9

The film formation method of any one of Supplementary Notes 1 to 4, wherein the first monomer is acyl halide, the second monomer is amine, and the polymer film formed on the substrate contains amide bonds.

### Supplementary Note 10

A film formation apparatus, comprising:
a chamber including a gas supply port and a gas exhaust port;
a substrate support provided in the chamber and configured to support a substrate including a base film and a resist provided on the base film and having a predetermined pattern formed thereon;
a lifting mechanism configured to raise and lower lift pins configured to support the substrate;
a gas supply configured to supply a gas into the chamber; and
a controller,
wherein the controller is configured to perform:
a) controlling the lifting mechanism to place the substrate loaded into the chamber on the substrate support via the lift pins;
b) controlling the gas supply to supply a gas of a first monomer into the chamber;
c) controlling the gas supply to supply a purge gas into the chamber;
d) controlling the gas supply to supply a gas of a second monomer into the chamber to form a polymer film on a surface of the substrate by a polymerization reaction between the first monomer and the second monomer; and
e) controlling the gas supply to supply a purge gas into the chamber, and
wherein a vapor pressure ratio of the first monomer or the second monomer whichever has a lower saturated vapor pressure is 0.05 or less.

In some embodiments, it is possible to improve the precision of a pattern formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film formation method, comprising:
a) loading a substrate including a base film and a resist provided on the base film and having a predetermined pattern formed thereon into a chamber;
b) supplying a gas of a first monomer into the chamber;
c) supplying a purge gas into the chamber;
d) supplying a gas of a second monomer into the chamber to form a polymer film on a surface of the substrate by a polymerization reaction between the first monomer and the second monomer; and
e) supplying the purge gas into the chamber,
wherein a vapor pressure ratio of the first monomer or the second monomer whichever has a lower saturated vapor pressure is 0.05 or less.

2. The film formation method of claim 1, wherein b), c), d), and e) are repeated multiple times in the named order.

3. The film formation method of claim 1, further comprising:
f) before b), supplying an oxygen-containing gas into the chamber and converting the oxygen-containing gas in the chamber into plasma.

4. The film formation method of claim 1, wherein in b), c), d), and e), the substrate is maintained at a temperature in a range of 20 degrees C. or higher and 120 degrees C. or lower.

5. The film formation method of claim 1, wherein the first monomer is isocyanate, the second monomer is amine, and the polymer film formed on the substrate contains urea bonds.

6. The film formation method of claim 1, wherein the first monomer is carboxylic acid anhydride, the second monomer is amine, and the polymer film formed on the substrate contains imide bonds.

7. The film formation method of claim 1, wherein the first monomer is epoxide, the second monomer is amine, and the polymer film formed on the substrate contains 2-aminoethanol bonds.

8. The film formation method of claim 1, wherein the first monomer is isocyanate, the second monomer is alcohol, and the polymer film formed on the substrate contains urethane bonds.

9. The film formation method of claim 1, wherein the first monomer is acyl halide, the second monomer is amine, and the polymer film formed on the substrate contains amide bonds.

10. A film formation apparatus, comprising:
a chamber including a gas supply port and a gas exhaust port;
a substrate support provided in the chamber and configured to support a substrate including a base film and a resist provided on the base film and having a predetermined pattern formed thereon;
a lifting mechanism configured to raise and lower lift pins configured to support the substrate;
a gas supply configured to supply a gas into the chamber; and
a controller,
wherein the controller is configured to perform:
a) controlling the lifting mechanism to place the substrate loaded into the chamber on the substrate support via the lift pins;
b) controlling the gas supply to supply a gas of a first monomer into the chamber;
c) controlling the gas supply to supply a purge gas into the chamber;
d) controlling the gas supply to supply a gas of a second monomer into the chamber to form a polymer film on a surface of the substrate by a polymerization reaction between the first monomer and the second monomer; and
e) controlling the gas supply to supply the purge gas into the chamber, and
wherein a vapor pressure ratio of the first monomer or the second monomer whichever has a lower saturated vapor pressure is 0.05 or less.
